(19) United States
(12) Patent Application Publication
(10) Pub. No.: US 2025/0079801 A1
(43) Pub. Date: Mar. 6, 2025

(54) LIGHT EMITTING DEVICE, MANUFACTURING METHOD FOR LIGHT EMITTING DEVICE, AND DISTANCE MEASURING DEVICE

(71) Applicant: SONY SEMICONDUCTOR SOLUTIONS CORPORATION, KANAGAWA (JP)

(72) Inventors: HIROSHI KATO, KANAGAWA (JP); ATSUSHI YAMAMOTO, KANAGAWA (JP); HIDEAKI MOGI, KANAGAWA (JP)

(21) Appl. No.: 18/261,725

(22) PCT Filed: Jan. 12, 2022
(86) PCT No.: PCT/JP2022/000729

§ 371 Date: Jul. 17, 2023

(30) Foreign Application Priority Data
Jan. 26, 2021 (JP) 2021-010424

(51) Int. Cl. H01S 5/183; G01S 7/481; H01S 5/02; H01S 5/42

(52) U.S. Cl. CPC H01S 5/18388; G01S 7/4814; H01S 5/0218; H01S 5/18305; H01S 5/423

(57) ABSTRACT

Provided are a light emitting device capable of suitably shaping light from a plurality of light emitting elements, a manufacturing method for a light emitting device, and a distance measuring device.

A light emitting device of the present disclosure includes: a substrate; a plurality of light emitting elements provided on a first surface of the substrate; and a plurality of structure bodies provided on a second surface of the substrate and through which light emitted from the plurality of light emitting elements is transmitted. At least any of the structure bodies includes a first structure body through which a first portion of the light is transmitted and a second structure body having a function different from a function of the first structure body and through which a second portion of the light is transmitted.

### TECHNICAL FIELD

The present disclosure relates to a light emitting device, a manufacturing method for a light emitting device, and a distance measuring device.

### BACKGROUND ART

As a type of semiconductor laser, a surface-emitting laser such as a vertical cavity surface emitting laser (VCSEL) is known. In general, in a light emitting device utilizing a surface-emitting laser, a plurality of light emitting elements is provided in a two-dimensional array on a front surface or a back surface of a substrate.

### CITATION LIST

### Patent Document

Patent Document 1: Japanese Patent Application Laid-Open No. 2004-526194

### SUMMARY OF THE INVENTION

### Problems to be Solved by the Invention

In the light emitting device as described above, for example, there is a case where it is desired to shape light emitted from the plurality of light emitting elements in various modes. For example, there are cases where it is desired to condense light, diffuse light, or scatter light. In this case, how to shape the light becomes a problem.

Therefore, the present disclosure provides a light emitting device capable of suitably shaping light from a plurality of light emitting elements, a manufacturing method for a light emitting device, and a distance measuring device.

### Solutions to Problems

A light emitting device according to a first aspect of the present disclosure includes: a substrate; a plurality of light emitting elements provided on a first surface of the substrate; and a plurality of structure bodies through which light emitted from the plurality of light emitting elements is transmitted, the plurality of structure bodies being provided on a second surface of the substrate, in which at least any of the structure bodies includes a first structure body through which a first portion of the light is transmitted and a second structure body through which a second portion of the light is transmitted, the second structure body having a function different from a function of the first structure body. As a result, for example, light from the plurality of light emitting elements can be suitably shaped such that light incident on a corresponding structure body from a certain light emitting element can be shaped in different modes between the first structure body and the second structure body.

Furthermore, in this first aspect, the first and second structure bodies may have a shape in which the second structure body annularly surrounds the first structure body. As a result, for example, a structure body that is desirably formed in a circular shape can be used as the first structure body, and a structure body that does not need to have a circular shape can be used as the second structure body.

Furthermore, in this first aspect, a boundary surface between the first and second structure bodies may be a plane. As a result, for example, it becomes possible to arrange the first and second structure bodies in a simple layout such as arrangement in which the first and second structure bodies are respectively on the left and right.

Furthermore, in this first aspect, the first structure body may be a lens, and the second structure body may be a structure body other than a lens. As a result, for example, light can be condensed or diffused by the first structure body, and light can be shaped in another mode by the second structure body.

Furthermore, in this first aspect, the first structure body may be a lens, and the second structure body may be a scatterer. As a result, for example, light can be condensed or diffused by the first structure body, and light can be scattered by the second structure body.

Furthermore, in this first aspect, the first and second structure bodies may be lenses having mutually different functions. As a result, for example, light incident on a corresponding structure body from a certain light emitting element can be shaped by two types of lenses.

Furthermore, in this first aspect, the first and second structure bodies may be lenses having mutually different curvatures. As a result, for example, two types of lenses can be achieved with a difference in curvature.

Furthermore, in this first aspect, at least any of the first and second structure bodies may be a convex lens, a concave lens, or a flat lens. As a result, for example, it is possible to shape light with an appropriate lens in accordance with a purpose of use of light.

Furthermore, in this first aspect, the first and second structure bodies may be provided on the second surface of the substrate, as a part of the substrate. As a result, for example, the first and second structure bodies can be easily formed by processing the substrate.

Furthermore, in this first aspect, the plurality of light emitting elements and the plurality of structure bodies may correspond to each other on a one-to-one basis, and light emitted from each light emitting element may be transmitted through one corresponding structure body. As a result, for example, light emitted from the plurality of light emitting elements can be shaped for every light emitting element.

Furthermore, in this first aspect, the substrate may be a semiconductor substrate containing gallium (Ga) and arsenic (As). As a result, for example, the substrate can be made suitable for the light emitting device.

Furthermore, in this first aspect, light emitted from the plurality of light emitting elements may be transmitted inside the substrate from the first surface to the second surface, and may be incident on the plurality of structure bodies. As a result, for example, it becomes possible to achieve a structure in which light is transmitted through the substrate and emitted from the light emitting device.

Furthermore, in this first aspect, the first surface of the substrate may be a front surface of the substrate, and the second surface of the substrate may be a back surface of the substrate. As a result, for example, the light emitting device can be a back-side emission type.

Furthermore, in this first aspect, the first structure body may condense or diffuse light from each of the light emitting element, and the second structure body may scatter light from each of the light emitting element. As a result, for example, light incident on a corresponding structure body from a certain light emitting element can be used by being condensed or diffused, or can also be used by being scattered.

Furthermore, in this first aspect, the first structure body may collimate light from each of the light emitting elements. As a result, for example, light incident on a corresponding structure body from a certain light emitting element can be used by being collimated or scattered.

A manufacturing method for a light emitting device according to a second aspect of the present disclosure includes: forming a plurality of light emitting elements on a first surface of a substrate; and forming, on a second surface of the substrate, a plurality of structure bodies through which light emitted from the plurality of light emitting elements is transmitted, in which at least any of the structure bodies is formed to include a first structure body through which a first portion of the light is transmitted and a second structure body through which a second portion of the light is transmitted, the second structure body having a function different from a function of the first structure body. As a result, for example, light from the plurality of light emitting elements can be suitably shaped such that light incident on a corresponding structure body from a certain light emitting element can be shaped in different modes between the first structure body and the second structure body.

Furthermore, in this second aspect, the first and second structure bodies may be simultaneously formed on the second surface of the substrate. As a result, for example, the first and second structure bodies can be formed with a small number of steps.

Furthermore, in this second aspect, the first and second structure bodies may be formed by forming one of the first and second structure bodies and then forming another one of the first and second structure bodies. As a result, for example, the first and second structure bodies can be precisely formed.

A distance measuring device according to a third aspect of the present disclosure includes: a light emitting device including a plurality of light emitting elements configured to generate light, the light emitting device being configured to irradiate a subject with the light from the light emitting elements; an imaging device configured to receive the light reflected by the subject and generate an image signal from the light; and a distance measuring unit configured to measure a distance to the subject on the basis of the image signal generated by the imaging device, in which the light emitting device includes: a substrate; the plurality of light emitting elements provided on a first surface of the substrate; and a plurality of structure bodies through which light emitted from the plurality of light emitting elements is transmitted, the plurality of structure bodies being provided on a second surface of the substrate, and at least any of the structure bodies includes a first structure body through which a first portion of the light is transmitted and a second structure body through which a second portion of the light is transmitted, the second structure body having a function different from a function of the first structure body. As a result, for example, light from the plurality of light emitting elements can be suitably shaped such that light incident on a corresponding structure body from a certain light emitting element can be shaped in different modes between the first structure body and the second structure body.

Furthermore, in the third aspect, the distance measuring unit may extract, from the image signal, first data corresponding to the first portion of the light transmitted through the first structure body and second data corresponding to the second portion of the light transmitted through the second structure body. As a result, for example, the first data corresponding to the first portion of the light transmitted through the first structure body and the second data corresponding to the second portion of the light transmitted through the second structure body can be selectively used for different purposes.

### BRIEF DESCRIPTION OF DRAWINGS

FIG. 1 is a block diagram illustrating a configuration of a distance measuring device of a first embodiment.

FIG. 2 is a cross-sectional view illustrating an example of a structure of a light emitting device of the first embodiment.

FIG. 3 is a cross-sectional view illustrating a structure of the light emitting device illustrated in B of FIG. 2.

FIG. 4 is a cross-sectional view illustrating a structure of the light emitting device of the first embodiment.

FIG. 5 is a plan view illustrating a structure of the light emitting device of the first embodiment.

FIG. 6 is a cross-sectional view for explaining an operation of the light emitting device of the first embodiment.

FIG. 7 is a cross-sectional view illustrating a structure of a light emitting device of a modification of the first embodiment.

FIG. 8 is a plan view illustrating a structure of a light emitting device of another modification of the first embodiment.

FIG. 9 is a cross-sectional view illustrating a structure of a light emitting device of another modification of the first embodiment.

FIG. 10 is a cross-sectional view illustrating a structure of a light emitting device of another modification of the first embodiment.

FIG. 11 is a plan view illustrating a structure of a light emitting device of another modification of the first embodiment.

FIG. 12 is a plan view illustrating a structure of a light emitting device of another modification of the first embodiment.

FIG. 13 is a plan view and cross-sectional views illustrating a structure of a light emitting device of another modification of the first embodiment.

FIG. 14 is a plan view and cross-sectional views illustrating a structure of a light emitting device of another modification of the first embodiment.

FIG. 15 is a cross-sectional view illustrating a manufacturing method for the light emitting device of the first embodiment.

FIG. 16 is a cross-sectional view (1/2) illustrating a manufacturing method for a light emitting device of a modification of the first embodiment.

FIG. 17 is a cross-sectional view (2/2) illustrating the manufacturing method for the light emitting device of the modification of the first embodiment.

### MODE FOR CARRYING OUT THE INVENTION

Hereinafter, an embodiment of the present disclosure will be described with reference to the drawings.

### First Embodiment

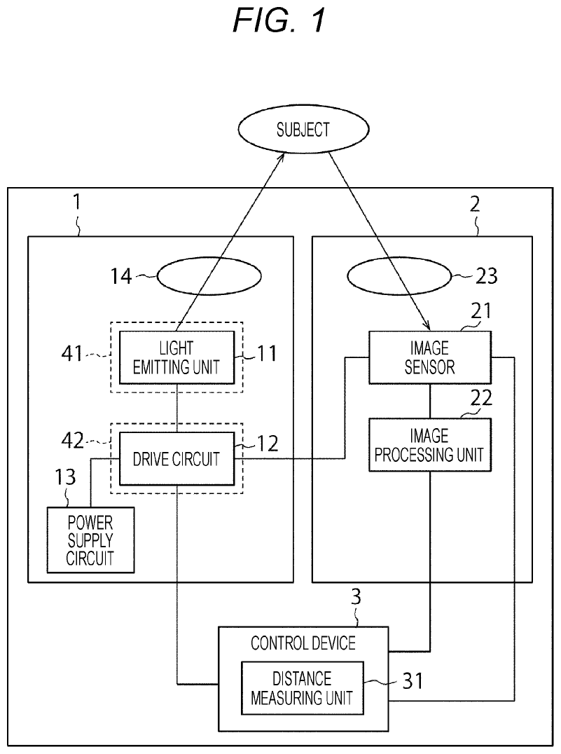

FIG. 1 is a block diagram illustrating a configuration of a distance measuring device according to a first embodiment.

The distance measuring device in FIG. 1 includes a light emitting device 1, an imaging device 2, and a control device 3. The distance measuring device in FIG. 1 irradiates a subject with light emitted from the light emitting device 1. The imaging device 2 receives light reflected by the subject and captures an image of the subject. The control device 3 measures (calculates) a distance to the subject by using an image signal output from the imaging device 2. The light emitting device 1 functions as a light source for the imaging device 2 to capture the image of the subject.

The light emitting device 1 includes a light emitting unit 11, a drive circuit 12, a power supply circuit 13, and a light-emitting side optical system 14. The imaging device 2 includes an image sensor 21, an image processing unit 22, and an imaging-side optical system 23. The control device 3 includes a distance measuring unit 31.

The light emitting unit 11 emits laser light for irradiating the subject. As described later, the light emitting unit 11 of the present embodiment includes a plurality of light emitting elements arranged in a two-dimensional array, and each light emitting element has a VCSEL structure. The subject is irradiated with light emitted from these light emitting elements. The light emitting unit 11 of the present embodiment is provided in a chip referred to as a laser diode (LD) chip 41.

The drive circuit 12 is an electric circuit that drives the light emitting unit 11, and the power supply circuit 13 is an electric circuit that generates a power supply voltage of the drive circuit 12. In the present embodiment, for example, the power supply circuit 13 generates a power supply voltage from an input voltage supplied from a battery in the distance measuring device, and the drive circuit 12 drives the light emitting unit 11 by using the power supply voltage. The drive circuit 12 of the present embodiment is provided in a substrate called a laser diode driver (LDD) substrate 42.

The light-emitting side optical system 14 includes various optical elements, and irradiates the subject with light from the light emitting unit 11 via these optical elements. Similarly, the imaging-side optical system 23 includes various optical elements, and receives light from the subject via these optical elements.

The image sensor 21 receives the light from the subject via the imaging-side optical system 23, and converts the light into an electric signal by photoelectric conversion. The image sensor 21 is, for example, a charge-coupled device (CCD) sensor or a complementary metal-oxide semiconductor (CMOS) sensor. The image sensor 21 of the present embodiment converts the above-described electronic signal from an analog signal to a digital signal with analog to digital (A/D) conversion, and outputs an image signal as a digital signal to the image processing unit 22. Furthermore, the image sensor 21 of the present embodiment outputs a frame synchronization signal to the drive circuit 12, and the drive circuit 12 causes the light emitting unit 11 to emit light at a timing corresponding to a frame period in the image sensor 21 on the basis of the frame synchronization signal.

The image processing unit 22 performs various types of image processing on the image signal output from the image sensor 21. The image processing unit 22 includes, for example, an image processing processor such as a digital signal processor (DSP).

The control device 3 controls various operations of the distance measuring device in FIG. 1, and controls, for example, light emitting operation by the light emitting device 1 or imaging operation by the imaging device 2. The control device 3 includes, for example, a central processing unit (CPU), a read-only memory (ROM), a random access memory (RAM), and the like.

The distance measuring unit 31 measures the distance to the subject on the basis of the image signal output from the image sensor 21 and subjected to the image processing by the image processing unit 22. The distance measuring unit 31 employs, for example, a structured light (STL) method or a Time of Flight (ToF) method as a distance measurement method. The distance measuring unit 31 may further measure a distance between the distance measuring device and the subject for every portion of the subject on the basis of the above-described image signal to identify a three-dimensional shape of the subject. Note that, further details of the distance measuring unit 31 of the present embodiment will be described later.

### (1) Structure of Light Emitting Device 1 of First Embodiment

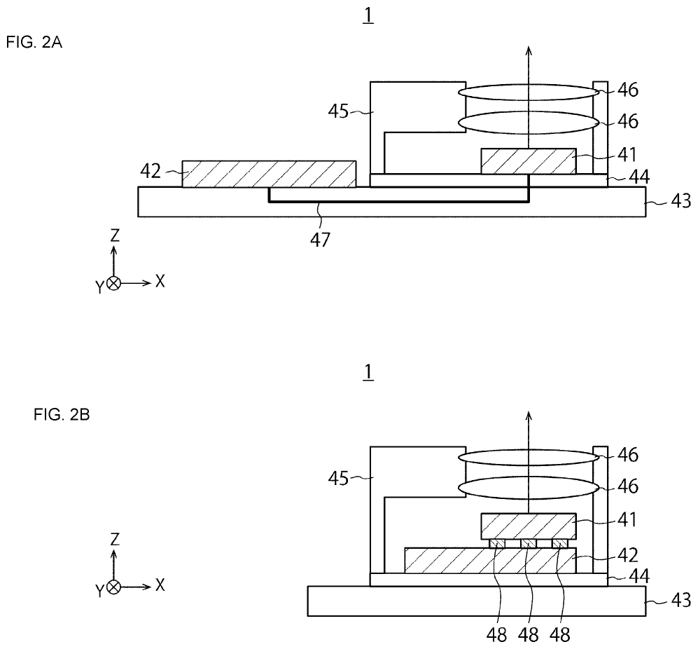

FIG. 2 is a cross-sectional view illustrating an example of a structure of the light emitting device 1 of the first embodiment.

A of FIG. 2 illustrates a first example of the structure of the light emitting device 1 of the present embodiment. The light emitting device 1 of this example includes the above-described LD chip 41 and LDD substrate 42, a mounting substrate 43, a heat dissipation substrate 44, a correction lens holding unit 45, one or more of correction lenses 46, and wiring 47.

A of FIG. 2 illustrates an X axis, a Y axis, and a Z axis perpendicular to each other. An X direction and a Y direction correspond to a lateral direction (horizontal direction), and a Z direction corresponds to a longitudinal direction (vertical direction). In addition, a +Z direction corresponds to an upward direction, and a −Z direction corresponds to a downward direction. The −Z direction may strictly match the gravity direction, or may not strictly match the gravity direction.

The LD chip 41 is arranged on the mounting substrate 43 with the heat dissipation substrate 44 interposed therebetween, and the LDD substrate 42 is also arranged on the mounting substrate 43. The mounting substrate 43 is, for example, a printed board. The image sensor 21 and the image processing unit 22 in FIG. 1 are also arranged on the mounting substrate 43 of the present embodiment. The heat dissipation substrate 44 is, for example, a ceramic substrate such as an aluminum oxide substrate or an aluminum nitride substrate.

The correction lens holding unit 45 is arranged on the heat dissipation substrate 44 so as to surround the LD chip 41, and holds one or more of correction lenses 46 above the LD chip 41. These correction lenses 46 are included in the above-described light-emitting side optical system 14 (FIG. 1). The light emitted from the light emitting unit 11 (FIG. 1) in the LD chip 41 is corrected by these correction lenses 46 and then irradiated to the subject (FIG. 1). A of FIG. 2 illustrates two correction lenses 46 held by the correction lens holding unit 45 as an example.

The wiring 47 is provided on the front surface, the back surface, the inside, or the like of the mounting substrate 43, and electrically connects the LD chip 41 and the LDD substrate 42. The wiring 47 is, for example, printed wiring provided on the front surface or the back surface of the mounting substrate 43 or via wiring penetrating the mounting substrate 43. The wiring 47 of the present embodiment further passes through the inside or the vicinity of the heat dissipation substrate 44.

B of FIG. 2 illustrates a second example of the structure of the light emitting device 1 of the present embodiment. The light emitting device 1 of this example includes the same components as those of the light emitting device 1 of the first example, but includes bumps 48 instead of the wiring 47.

In B of FIG. 2, the LDD substrate 42 is arranged on the heat dissipation substrate 44, and the LD chip 41 is arranged on the LDD substrate 42. By arranging the LD chip 41 on the LDD substrate 42 in this manner, the size of the mounting substrate 43 can be reduced as compared with the case of the first example. In B of FIG. 2, the LD chip 41 is arranged on the LDD substrate 42 with the bumps 48 interposed therebetween, and is electrically connected to the LDD substrate 42 by the bumps 48.

Hereinafter, the light emitting device 1 of the present embodiment will be described as having the structure of the second example illustrated in B of FIG. 2. However, the following description is also applicable to the light emitting device 1 having the structure of the first example except for the description of the structure specific to the second example.

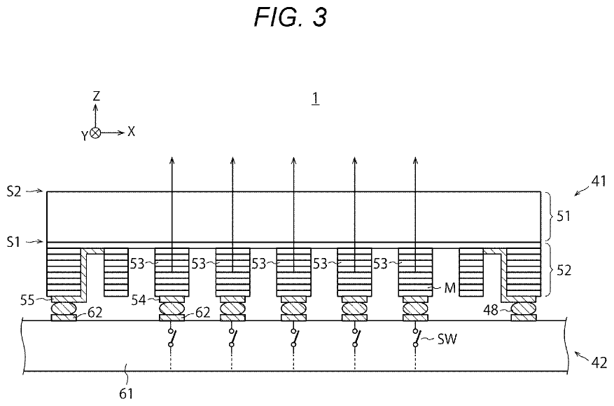

FIG. 3 is a cross-sectional view illustrating a structure of the light emitting device 1 illustrated in B of FIG. 2.

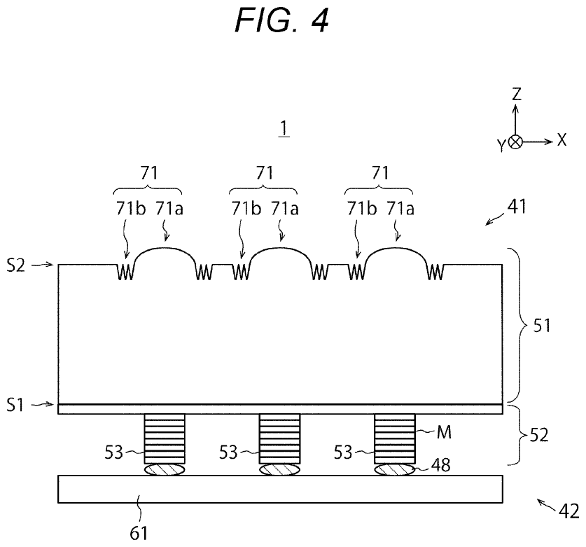

FIG. 3 illustrates cross sections of the LD chip 41 and the LDD substrate 42 in the light emitting device 1. As illustrated in FIG. 3, the LD chip 41 includes a substrate 51, a laminated film 52, a plurality of light emitting elements 53, a plurality of anode electrodes 54, and a plurality of cathode electrodes 55, and the LDD substrate 42 includes a substrate 61 and the plurality of connection pads 62. Note that, in FIG. 3, illustration of a structure body 71 to be described later is omitted (see FIG. 4).

The substrate 51 is, for example, a semiconductor substrate such as a gallium arsenide (GaAs) substrate. FIG. 3 illustrates a front surface S1 of the substrate 51 facing the −Z direction and a back surface S2 of the substrate 51 facing the +Z direction. The front surface S1 is an example of a first surface of the present disclosure, and the back surface S2 is an example of a second surface of the present disclosure.

The laminated film 52 includes a plurality of layers laminated on the front surface S1 of the substrate 51. Examples of these layers include an n-type semiconductor layer, an active layer, a p-type semiconductor layer, a light reflecting layer, and an insulating layer having a light emission window. The laminated film 52 includes a plurality of mesa portions M protruding in the −Z direction. Parts of these mesa portions M are the plurality of light emitting elements 53.

The light emitting elements 53 are provided on the front surface S1 of the substrate 51, as a part of the laminated film 52. The light emitting elements 53 of the present embodiment have a VCSEL structure and emit light in the +Z direction. As illustrated in FIG. 3, light emitted from the light emitting elements 53 is transmitted inside the substrate 51 from the front surface S1 to the back surface S2, and is incident on the above-described correction lenses 46 (FIG. 2) from the substrate 51. Thus, the LD chip 41 of the present embodiment is a back-side emission type VCSEL chip.

The anode electrodes 54 are formed on lower surfaces of the light emitting elements 53. The cathode electrodes 55 are formed on lower surfaces of the mesa portions M other than the light emitting elements 53, and extends up to a lower surface of the laminated film 52 that is present between the mesa portions M. Each light emitting element 53 emits light when a current flows between the corresponding anode electrode 54 and the corresponding cathode electrode 55.

As described above, the LD chip 41 is arranged on the LDD substrate 42 with the bumps 48 interposed therebetween, and is electrically connected to the LDD substrate 42 by the bumps 48. Specifically, the connection pads 62 are formed on the substrate 61 included in the LDD substrate 42, and the mesa portions M are arranged on the connection pads 62 with the bumps 48 interposed therebetween. Each mesa portion M is arranged on the bump 48 via the anode electrode 54 or the cathode electrode 55. The substrate 61 is, for example, a semiconductor substrate such as a silicon (Si) substrate.

The LDD substrate 42 includes the drive circuit 12 that drives the light emitting unit 11 (FIG. 1). FIG. 3 schematically illustrates a plurality of switches SW included in the drive circuit 12. Each switch SW is electrically connected to the corresponding light emitting element 53 via the bump 48. The drive circuit 12 of the present embodiment can control (turn on and off) these switches SW for every switch SW. Therefore, the drive circuit 12 can drive the plurality of light emitting elements 53 for every light emitting element 53. As a result, it is possible to precisely control the light emitted from the light emitting unit 11, for example, by causing only the light emitting elements 53 necessary for distance measurement to emit light. Such individual control of the light emitting elements 53 can be implemented by arranging the LDD substrate 42 below the LD chip 41, so that each light emitting element 53 is easily electrically connected to the corresponding switch SW.

FIG. 4 is a cross-sectional view illustrating a structure of the light emitting device 1 of the first embodiment.

FIG. 4 illustrates cross sections of the LD chip 41 and the LDD substrate 42 in the light emitting device 1. As described above, the LD chip 41 includes the substrate 51, the laminated film 52, the plurality of light emitting elements 53, the plurality of anode electrodes 54, and the plurality of cathode electrodes 55, and the LDD substrate 42 includes the substrate 61 and the plurality of connection pads 62. However, in FIG. 4, illustration of the anode electrodes 54, the cathode electrodes 55, and the connection pads 62 is omitted.

The LD chip 41 of the present embodiment includes a plurality of light emitting elements 53 on the front surface S1 of the substrate 51 and a plurality of structure bodies 71 on the back surface S2 of the substrate 51. Similarly to the light emitting element 53, these structure bodies 71 are arranged in a two-dimensional array. The structure body 71 of the present embodiment corresponds to the light emitting element 53 on a one-to-one basis, and each structure body 71 is arranged in the +Z direction of one light emitting element 53.

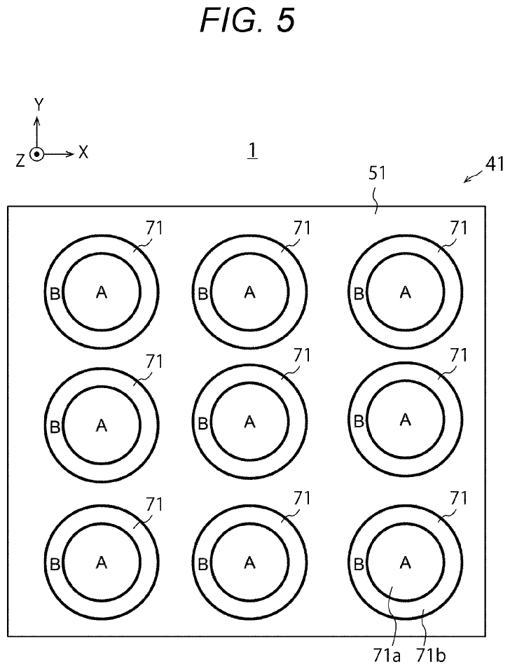

Each structure body 71 includes a first structure body 71a and a second structure body 71b. The first structure body 71a is, for example, a lens. The first structure body 71a of the present embodiment is a convex lens having a convex upper surface, and can condense light. As described later, the first structure body 71a may be a lens other than the convex lens, for example, a concave lens or a flat lens. The second structure body 71b is, for example, a structure body other than a lens. The second structure body 71b of the present embodiment is a scatterer including a plurality of dot-shaped fine protrusions, and can scatter light. As described later, the second structure body 71b may be a structure body other than the scatterer, for example, a lens having a function different from a function of the lens of the first structure body 71a. As will be described later, the first structure body 71a and the second structure body 71b of the present embodiment have a shape in which the second structure body 71b annularly surrounds the first structure body 71a (see FIG. 5). For example, the first structure body 71a has a circular shape in plan view, and the second structure body 71b has an annular shape in plan view.

The structure body 71 of the present embodiment is provided as a part of the substrate 51 on the back surface S2 of the substrate 51. Specifically, the structure body 71 of the present embodiment is formed by processing the substrate 51 from the back surface S2. According to the present embodiment, the structure body 71 can be easily formed by processing the substrate 51.

Note that the structure body 71 may be formed on a film provided on the substrate 51, instead of being formed on the substrate 51. As a result, it is possible to suppress damage to the substrate 51 due to processing on the substrate 51, while forming the light emitting element 53 on the substrate 51 (GaAs substrate) suitable for improving performance of the light emitting element 53. Whereas, according to the present embodiment, by forming the structure body 71 on the substrate 51, it is possible to downsize the light emitting device 1 while forming the light emitting element 53 on the substrate 51 (GaAs substrate) suitable for improving performance of the light emitting element 53.

Light emitted from the plurality of light emitting elements 53 described above is transmitted inside the substrate 51 from the front surface S1 to the back surface S2, and is incident on the structure body 71. In the present embodiment, light emitted from each light emitting element 53 is incident on one corresponding structure body 71. The light incident on each structure body 71 is emitted from the substrate 51 by being transmitted through each structure body 71, and is incident on the above-described correction lens 46 (FIG. 2). The subject (FIG. 1) is irradiated with the light having passed through the correction lens 46.

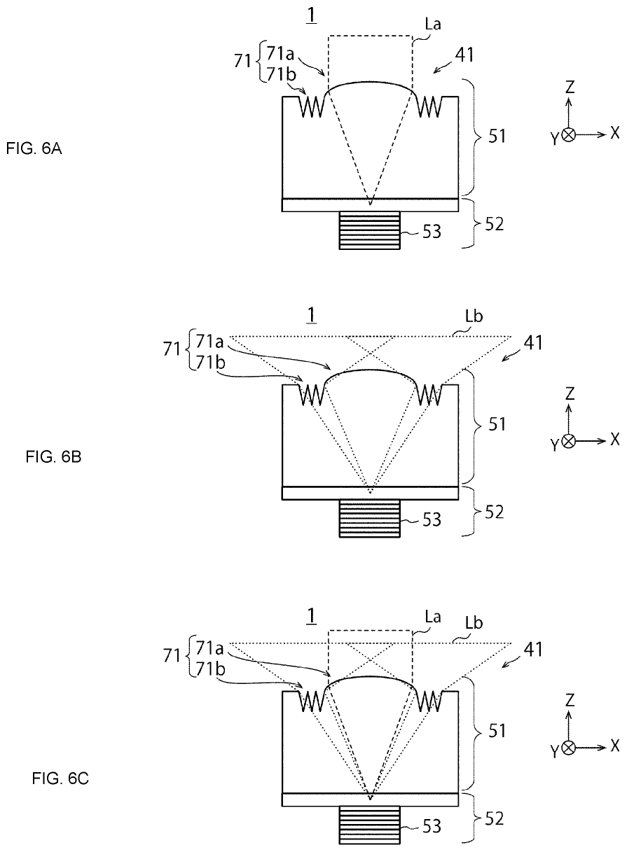

When light emitted from each light emitting element 52 is incident on one corresponding structure body 71, the light is incident on the first structure body 71a and the second structure body 71b of the structure body 71 as described later (see FIG. 6). Specifically, a first portion of the light is incident on the first structure body 71a, and a second portion of the light is incident on the second structure body 72b. In the present embodiment, a central portion and a peripheral portion of light incident on each structure body 71 are the first portion and the second portion, respectively. The first portion is transmitted through the first structure body 71b and is incident on the correction lens 46, and the second portion is transmitted through the second structure body 71b and is incident on the correction lens 46.

As described above, the light emitting device 1 of the present embodiment includes the structure body 71 that shapes light emitted from the light emitting element 53, and each structure body 71 includes the first structure body 71a that shapes the first portion of the light and the second structure body 71b that shapes the second portion of the light. Therefore, according to the present embodiment, light from the light emitting element 53 can be suitably shaped such that light incident on the structure body 71 from the light emitting element 53 can be shaped in different modes in the first structure body 71a and the second structure body 71b.

If a lens such as the first structure body 71a is arranged above a certain light emitting element 53 and a scatterer such as the second structure body 71b is arranged above another light emitting element 53, both condensed light and the scattered light can be generated. In this case, at that time of generating the condensed light, the light emitting element 53 below the scatterer is unnecessary. Whereas, at the time of generating the scattered light, the light emitting element 53 below the lens is unnecessary. As a result, the light emitting element 53 that is not used is wasted.

Whereas, each light emitting element 53 of the present embodiment is used for generating either condensed light or scattered light. Therefore, according to the present embodiment, since each structure body 71 includes the first structure body 71a and the second structure body 71b, it is possible to reduce waste of the light emitting element 53. In other words, according to the present embodiment, it is possible to make the distance measuring device multifunctional with a small number of light emitting elements 53, and it is possible to achieve low power consumption, miniaturization, weight reduction, and high accuracy of the distance measuring device.

FIG. 5 is a plan view illustrating a structure of the light emitting device 1 of the first embodiment.

In FIG. 5, nine pieces (=3×3) of structure body 71 are arranged in a two-dimensional array on the back surface S2 of the substrate 51, specifically, arranged in a square lattice pattern. FIG. 5 illustrates a region A of the first structure body 71a in each structure body 71 and a region B of the second structure body 71b in each structure body 71. In the present embodiment, the region A has a circular shape, and the region B has an annular shape surrounding the region A. Therefore, in each structure body 71, the second structure body 71b annularly surrounds the first structure body 71a. Note that the number of the structure bodies 71 on the back surface S2 of the substrate 51 may be other than nine, and arrangement of these structure bodies 71 may be other than the arrangement illustrated in FIG. 5.

As described above, an example of the first structure body 71a is a lens, and an example of the second structure body 71b is a scatterer. In many cases, a planar shape of the lens is desirably a circular shape. According to the present embodiment, by using a lens as the first structure body 71a, the planar shape of the lens can be made a circular shape. Whereas, a planar shape of the scatterer does not need to be a circular shape in many cases. Therefore, the second structure body 71b of the present embodiment is a scatterer, and the planar shape of the scatterer is a non-circular shape. Note that the second structure body 71b of the present embodiment includes a plurality of protrusions regularly arranged two-dimensionally (FIG. 4), but may include a plurality of protrusions irregularly arranged two-dimensionally.

FIG. 6 is a cross-sectional view for explaining an operation of the light emitting device 1 of the first embodiment.

A of FIG. 6 illustrates a first portion La transmitted through the first structure body 71a, in light emitted from the light emitting element 53. B of FIG. 6 illustrates a second portion Lb transmitted through the second structure body 71b, in light emitted from the light emitting element 53. C of FIG. 6 collectively illustrates the first portion La and the second portion Lb.

In the present embodiment, light emitted from each light emitting element 53 is incident on the corresponding structure body 71 as illustrated in C of FIG. 6. The light includes the first portion La incident on the first structure body 71a and the second portion Lb incident on the second structure body 71b. The first structure body 71a is, for example, a convex lens, and has a function of condensing incident light. Whereas, the second structure body 71b is, for example, a scatterer, and has a function of scattering incident light. Therefore, the first portion La transmitted through the first structure body 71a becomes condensed light as illustrated in A of FIG. 6, and the second portion Lb transmitted through the second structure body 71b becomes scattered light as illustrated in B of FIG. 6. As illustrated in C of FIG. 6, the structure body 71 simultaneously emits the condensed light (the first portion La) and the scattered light (the second portion Lb).

Note that the first structure body 71a of the present embodiment collimates the first portion La by condensing the first portion La. Therefore, the first portion La transmitted through the first structure body 71a of the present embodiment becomes parallel light.

Next, the distance measuring unit 31 illustrated in FIG. 1 will be described.

As described above, the distance measuring unit 31 measures a distance to a subject on the basis of an image signal generated by the imaging device 2. The image signal of the present embodiment includes first data corresponding to the first portion La transmitted through the first structure body 71a of each structure body 71 and second data corresponding to the second portion Lb transmitted through the second structure body 71b of each structure body 71. Therefore, the distance measuring unit 31 performs information processing of extracting the first data and the second data from the image signal, and measures the distance to the subject by using the extracted first data and the extracted second data. For example, the distance measuring unit 31 may measure a distance to a certain portion of the subject by using the first data and measure a distance to another portion of the subject by using the second data. Furthermore, the distance measuring unit 31 may measure the distance to the subject by a combination of first processing using the first data and second processing using the second data.

The first data and the second data may be extracted from the image signal in any mode. For example, the distance measuring unit 13 may include: a separation unit that separates an image signal into a condensed light component and a scattered light component; a first computation unit that extracts the first data from the condensed light component; and a second computation unit that extracts the second data from the scattered light component. In this case, the distance measuring unit 13 may measure the distance to the subject on the basis of the first data extracted by the first computation unit and the second data extracted by the second computation unit. Furthermore, the distance measuring unit 13 may include a first output unit that externally outputs the first data extracted by the first computation unit and a second output unit that externally outputs the second data extracted by the second computation unit. Furthermore, such first and second output units may be provided outside the distance measuring unit 13 or outside the control device 3.

### (2) Structure of Light Emitting Device 1 of Modification of First Embodiment

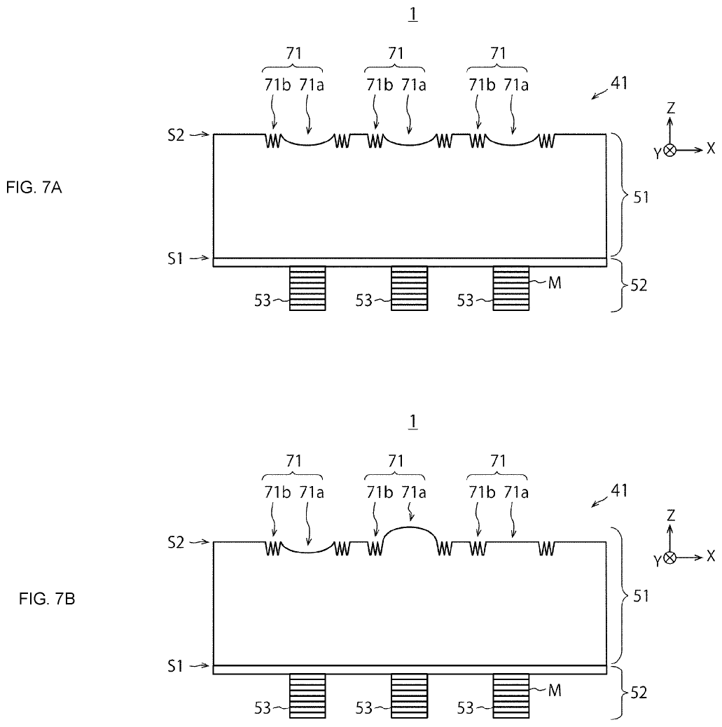

FIGS. 7 to 14 are cross-sectional views and a plan view illustrating a structure of a light emitting device 1 of various modifications of the first embodiment.

In the light emitting device 1 illustrated in A of FIG. 7, each of the first structure bodies 71a is a concave lens having a concave upper surface, and can diffuse light. The first structure body 71a of the present embodiment may be any type of lens according to a purpose of use of light.

The light emitting device 1 illustrated in B of FIG. 7 includes various types of lenses, as the first structure body 71a. B of FIG. 7 illustrates, as an example of the first structure body 71a, a convex lens having a convex upper surface, a concave lens having a concave upper surface, and a flat lens having a flat upper surface. A state in which the flat lens is present above the light emitting element 53 can also be said to be a state in which the lens is not present above the light emitting element 53. As described above, the light emitting device 1 of the present embodiment may include two or more types of lenses as the first structure body 71a.

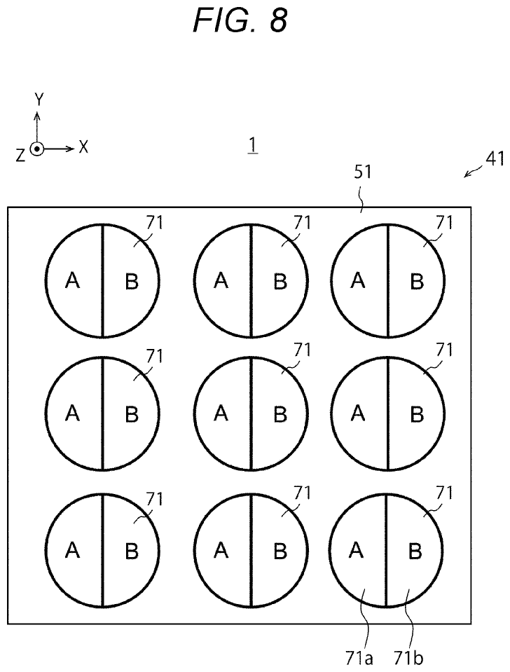

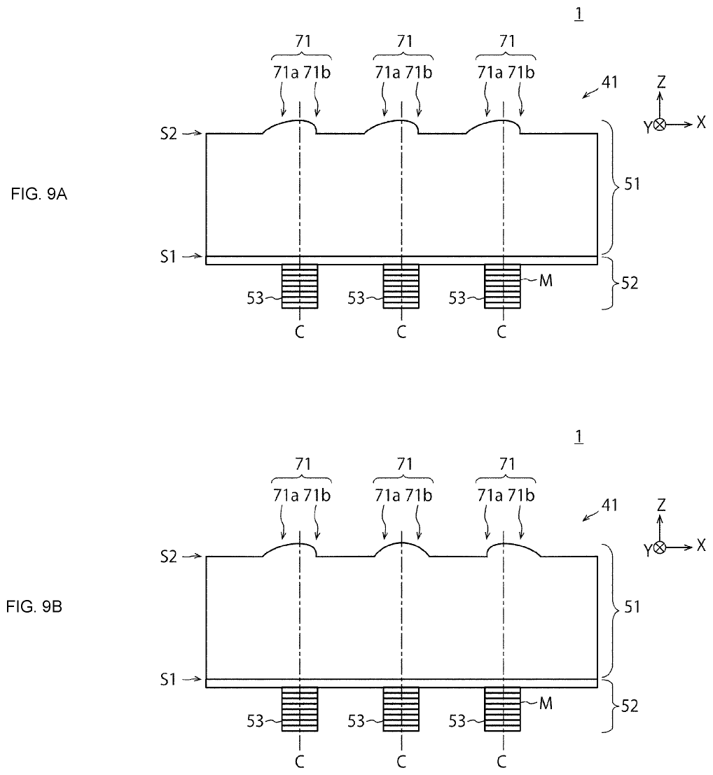

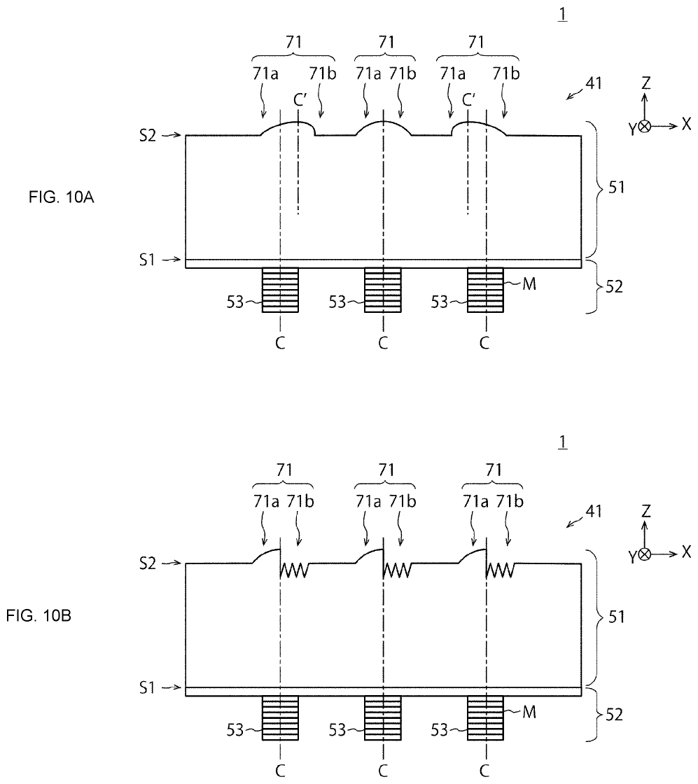

The light emitting device 1 illustrated in FIG. 8 is a modification of the light emitting device 1 illustrated in FIG. 5. In FIG. 5, the region A of the first structure body 71a has a circular shape, and the region B of the second structure body 71b has an annular shape. Whereas, in FIG. 8, the region A of the first structure body 71a has a semicircular shape, and the region B of the second structure body 71b has also a semicircular shape. Therefore, a boundary surface between the region A and the region B illustrated in FIG. 5 has a cylindrical shape extending in the Z direction, whereas a boundary surface between the region A and the region B illustrated in FIG. 8 is a plane extending in the Z direction. In FIG. 8, since the region A and the region B are arranged side by side, the boundary surface is a YZ plane. According to the present modification, since the region A and the region B can be set by sectioning a region of each structure body 71 into two on a plane, the first structure body 71a and the second structure body 71b can be arranged in a simple layout. Note that, an area of the region A and an area of the region B may be the same or different. Hereinafter, structures illustrated in A of FIG. 9 to B of FIG. 10 will be described as specific examples of the present modification.

A of FIG. 9 illustrates a plane C (the YZ plane) passing through a center of each light emitting element 53. Each structure body 71 of the present modification includes the first structure body 71a that is a convex lens and the second structure body 71b that is a convex lens having a function different from a function of the convex lens of the first structure body 71a, and the plane C is a boundary surface between the first structure body 71a and the second structure body 71b. Specifically, the first structure body 71a and the second structure body 71b of the present modification are convex lenses having mutually different curvatures, the first structure body 71a has a large radius of curvature, and the second structure body 71b has a small radius of curvature. Therefore, the first structure body 71a and the second structure body 71b of the present modification can condense light in different modes.

Each structure body 71 illustrated in B of FIG. 9 also includes the first structure body 71a that is a convex lens and the second structure body 71b that is a convex lens. However, the light emitting device 1 of the present modification includes not only the structure body 71 in which a curvature radius of the first structure body 71a is larger than a curvature radius of the second structure body 71b but also the structure body 71 in which a curvature radius of the first structure body 71a is smaller than a curvature radius of the second structure body 71b. As a result, similarly to the light emitting device 1 illustrated in B of FIG. 7, light can be shaped in various modes for every light emitting element 53 (for every structure body 71).

Note that the light emitting device 1 illustrated in B of FIG. 9 exceptionally includes the structure body 71 having the same function between the first structure body 71a and the second structure body 71b, in addition to the structure body 71 having different functions between the first structure body 71a and the second structure body 71b. Specifically, the structure body 71 at the center illustrated in B of FIG. 9 includes the first structure body 71a and the second structure body 71b having the same size and the same radius of curvature, and these first structure body 71a and second structure body 71b can condense light to the same extent. In this case, the function of shaping light in different modes between the first structure body 71a and the second structure body 71b can be exerted by the structure body 71 other than the structure body 71 at the center. This configuration similarly applies to the light emitting device 1 illustrated in A of FIG. 10 described later.

A of FIG. 10 illustrates a plane C (the YZ plane) passing through a center of each light emitting element 53 and a plane C′ (the YZ plane) parallel to the plane C. Each structure body 71 of the present modification has a shape similar to each structure body 71 illustrated in B of FIG. 9, but the plane C′ rather than the plane C is a boundary surface between the first structure body 71a and the second structure body 71b. In the structure body 71 on a left side illustrated in A of FIG. 10, the plane C′ is located on a right side of the plane C. In the structure body 71 on a right side illustrated in B of FIG. 10, the plane C′ is located on a left side of the plane C. This arrangement makes it possible to perform pupil correction on light emitted from these structure bodies 71.

Each structure body 71 illustrated in B of FIG. 10 includes the first structure body 71a that is a lens and the second structure body 71b that is a structure body other than a lens. The first structure body 71a is, for example, a convex lens. The second structure body 71b is, for example, a scatterer. Each structure body 71 of the present modification has a shape obtained by deforming shapes of the regions A and B of each structure body 71 illustrated in FIG. 4.

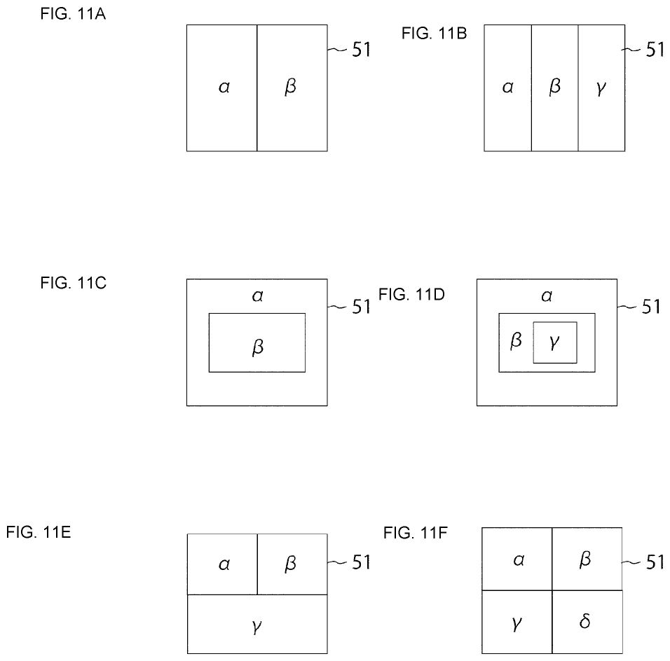

A to F of FIG. 11 are plan views schematically illustrating a structure of a light emitting device 1 of another modification of the present embodiment.

In A to F of FIG. 11, a reference sign α indicates a region where a first type structure body 71 is arranged on the back surface S2 of the substrate 51, a reference sign β indicates a region where a second type structure body 71 is arranged on the back surface S2 of the substrate 51, a reference numeral γ indicates a region where a third type structure body 71 is arranged on the back surface S2 of the substrate 51, and a reference sign δ indicates a region where a fourth type structure body 71 is arranged on the back surface S2 of the substrate 51. The first type structure body 71 includes, for example, the first structure body 71a that is a convex lens and the second structure body 71b that is a scatterer. The second type structure body 71 includes, for example, the first structure body 71a that is a concave lens and the second structure body 71b that is a scatterer. The third type structure body 71 includes, for example, the first structure body 71a that is a flat lens and the second structure body 71b that is a scatterer. The structure body 71 of the fourth type includes, for example, the first structure body 71a and the second structure body 71b that are convex lenses having mutually different curvatures. Hereinafter, these regions are referred to as an “α region”, a “β region”, a “γ region”, and a “δ region”.

In A of FIG. 11, the back surface S2 of the substrate 51 is sectioned into two regions, one region is the α region, and another region is the β region. For example, in a case where N×M pieces of structure body 71 are arranged on the back surface S2 of the substrate 51, the α region includes (N/2)×M pieces of structure body 71, and the β region includes (N/2)×M pieces of structure body 71 (N and M are integers of 2 or more). Similarly, in C of FIG. 11, the back surface S2 of the substrate 51 is sectioned into two regions.

In B of FIG. 11, the back surface S2 of the substrate 51 is sectioned into three regions, and these regions are the α region, the β region, and the γ region. For example, in a case where N×M pieces of structure body 71 are arranged on the back surface S2 of the substrate 51, the α region includes (N/3)×M pieces of structure body 71, the β region includes (N/3)×M pieces of structure body 71, and the γ region includes (N/3)×M pieces of structure body 71. Similarly, in D of FIG. 11 and E of FIG. 11, the back surface S2 of the substrate 51 is sectioned into three regions.

In F of FIG. 11, the back surface S2 of the substrate 51 is sectioned into four regions, and these regions are the α region, the β region, the γ region, and the δ region. For example, in a case where N×M pieces of structure body 71 are arranged on the back surface S2 of the substrate 51, the α region includes (N/2)×(M/2) pieces of structure bodies 71, the β region includes (N/2)×(M/2) pieces of structure bodies 71, the γ region includes (N/2)×(M/2) pieces of structure bodies 71, and the δ region includes (N/2)×(M/2) pieces of structure bodies 71.

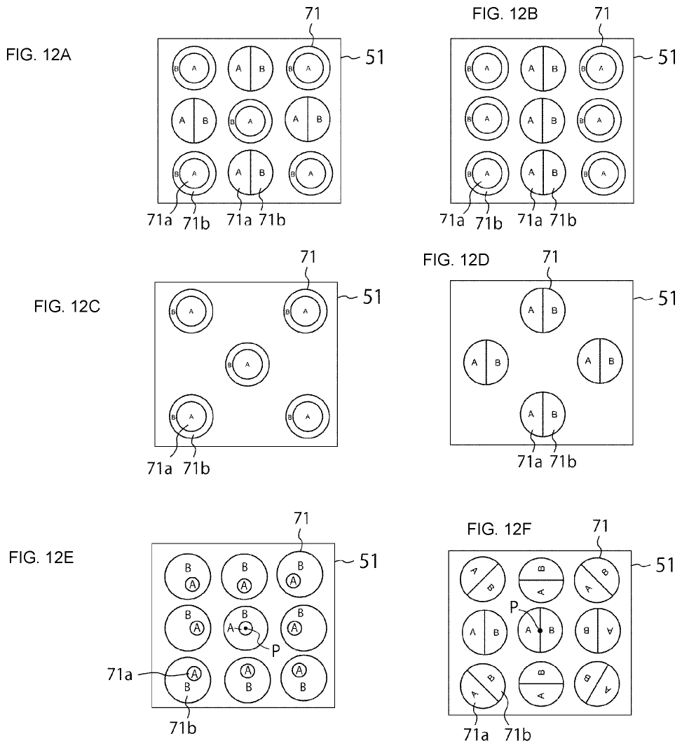

A to F of FIG. 12 are plan views schematically illustrating a structure of a light emitting device 1 of another modification of the present embodiment. In A to F of FIG. 11, the back surface S2 of the substrate 51 is sectioned into several regions, whereas in A to F of FIG. 12, the back surface S2 of the substrate 51 is subsectioned into many regions.

A of FIG. 12 illustrates nine pieces of structure body 71 provided on the back surface S2 of the substrate 51. These structure bodies 71 include the structure body 71 including the regions A and B having the shape illustrated in FIG. 5 and the structure body 71 including the regions A and B having the shape illustrated in FIG. 8. This configuration similarly applies to B of FIG. 12. However, A of FIG. 12 and FIG. 12B are different from each other in the layout of the structure body 71 having the shape illustrated in FIG. 5 and the structure body 71 having the shape illustrated in FIG. 8.

The structure bodies 71 illustrated in C of FIG. 12 include the structure body 71 including the regions A and B having the shape illustrated in FIG. 5. However, the back surface S2 of the substrate 51 illustrated in C of FIG. 12 includes a region where the structure body 71 is arranged and a region where the structure body 71 is not arranged. This configuration similarly applies to D of FIG. 12. The structure bodies 71 illustrated in D of FIG. 12 include the structure body 71 including the regions A and B having the shape illustrated in FIG. 8. However, the back surface S2 of the substrate 51 illustrated in D of FIG. 12 includes a region where the structure body 71 is arranged and a region where the structure body 71 is not arranged. Note that C of FIG. 12 and FIG. 12D are different in the layout of these structure bodies 71.

E of FIG. 12 illustrates nine pieces of structure body 71 provided on the back surface S2 of the substrate 51. A reference sign P indicates a center of the substrate 51. The structure bodies 71 illustrated in E of FIG. 12 include the structure body 71 including the regions A and B having the shape illustrated in FIG. 5, and pupil correction can be applied to light emitted from these structure bodies 71. This configuration similarly applies to F of FIG. 12. The structure bodies 71 illustrated in F of FIG. 12 include the structure body 71 including the regions A and B having the shape illustrated in FIG. 8, and pupil correction can be applied to light emitted from these structure bodies 71. Note that, in E of FIG. 12, pupil correction is implemented by changing a position of the region A with respect to the region B for each structure body 71. Whereas, in F of FIG. 12, pupil correction is implemented by changing a direction of a boundary surface between the region A and the region B for each structure body 71.

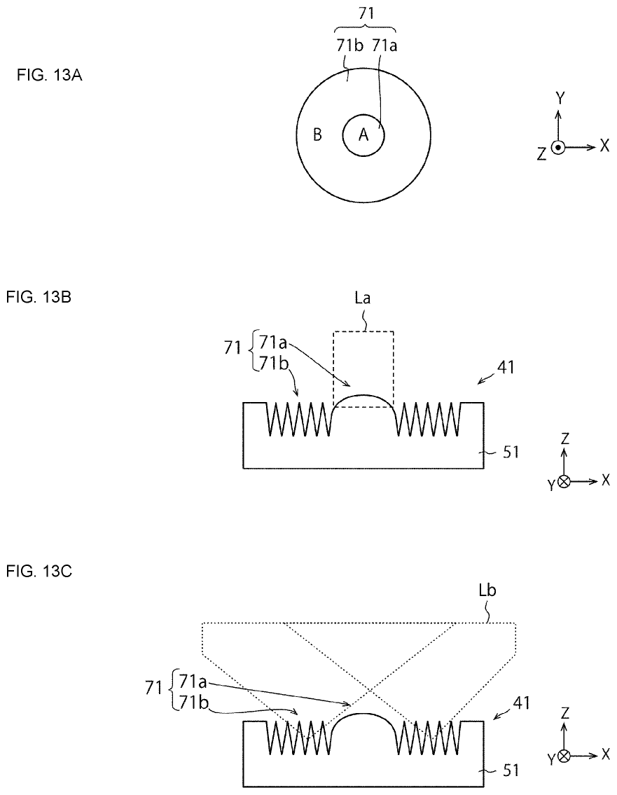

A to C of FIG. 13 are a plan view and cross-sectional views illustrating a structure of a light emitting device 1 of another modification of the present embodiment. A of FIG. 13 illustrates a planar shape of one structure body 71. B of FIG. 13 illustrates light (the first portion La) transmitted through the first structure body 71a of the structure body 71. C of FIG. 13 illustrates light (the second portion Lb) transmitted through the second structure body 71b of the structure body 71.

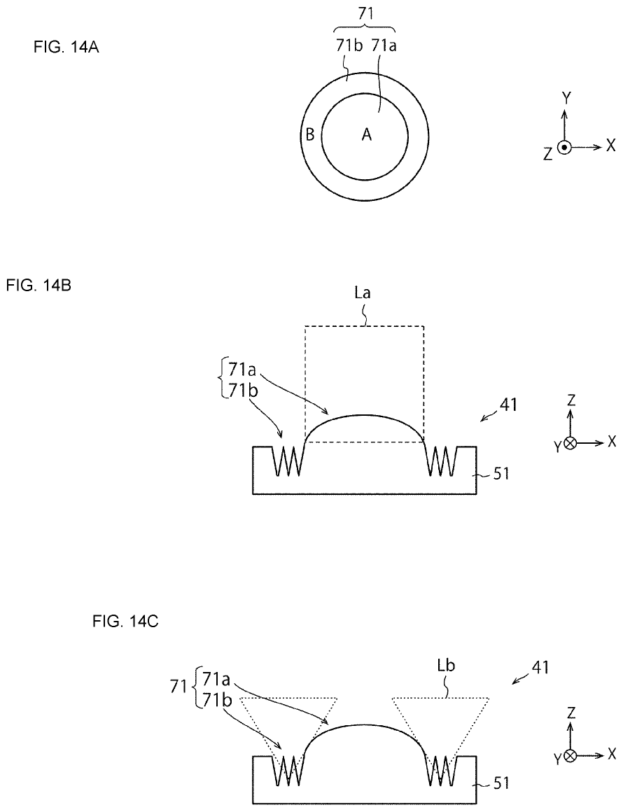

This configuration similarly applies to A to C of FIG. 14. However, in the structure body 71 illustrated in A to C of FIG. 13, a ratio of an area of the region A to an area of the region B is set to be small. Whereas, in the structure body 71 illustrated in A to C of FIG. 14, a ratio of an area of the region A to an area of the region B is set to be large.

The structure body illustrated in A to C of FIG. 13 can be employed, for example, in a case where it is desired to enhance the effect of the second structure body 71b (for example, a scatterer). Whereas, the structure body illustrated in A to C of FIG. 14 can be employed, for example, in a case where it is desired to enhance the effect of the first structure body 71a (for example, a lens). As described above, according to the present embodiment, the function of the structure body 71 can be adjusted by adjusting the shapes of the regions A and B.

### (3) Manufacturing Method for Light Emitting Device 1 of First Embodiment

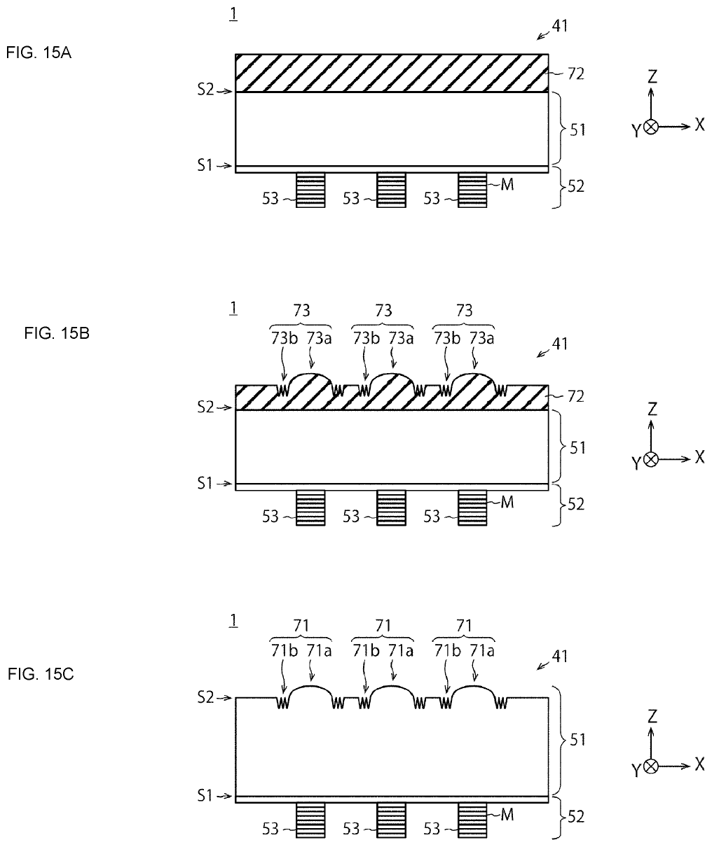

FIG. 15 is a cross-sectional view illustrating a manufacturing method for the light emitting device 1 of the first embodiment.

First, after the laminated film 52 and the light emitting element 53 are formed on the front surface S1 of the substrate 51, a mask film 72 is formed on the back surface S2 of the substrate 51 (A of FIG. 15). The mask film 72 is, for example, a resist film.

Next, an upper surface of the mask film 72 is processed to form a plurality of mask portions 73 having the same shape as the structure body 71, in a part of the mask film 72 (B of FIG. 15). Each mask portion 73 is formed to include a first mask portion 73a having the same shape as the first structure body 71a and a second mask portion 73b having the same shape as the second structure body 71b. The processing of the upper surface of the mask film 72 may be performed by, for example, grayscale lithography and dry etching, or may be performed by imprinting. The first mask portion 73a and the second mask portion 73b illustrated in B of FIG. 15 have shapes of a convex lens and a scatterer, respectively.

Next, the back surface S2 of the substrate 51 is processed by dry etching using the mask film 72 as an etching mask (C of FIG. 15). As a result, a shape of the mask film 72 is transferred to the substrate 51, and a plurality of structure bodies 71 is formed on the back surface S2 of the substrate 51. Each structure body 71 is formed to include the first structure body 71a and the second structure body 71b.

In this way, the light emitting device 1 illustrated in FIG. 4 is manufactured. According to the present method, the first structure body 71a and the second structure body 71b of each structure body 71 can be simultaneously formed on the back surface S2 of the substrate 51. Note that, when the light emitting device 1 of any of the above modifications is manufactured, the mask portion 72 having the same shape as the structure body 71 of the modification is formed in the step of B of FIG. 15.

### (4) Manufacturing Method for Light Emitting Device 1 of Modification of First Embodiment

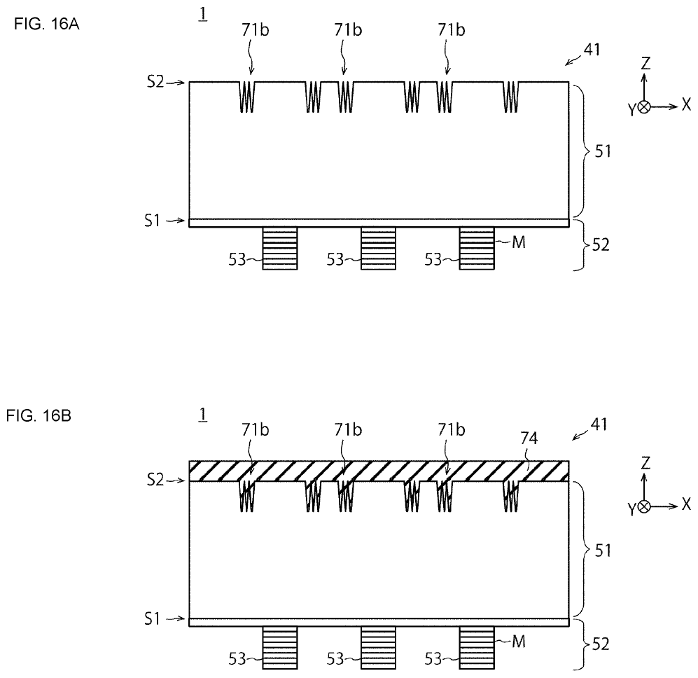

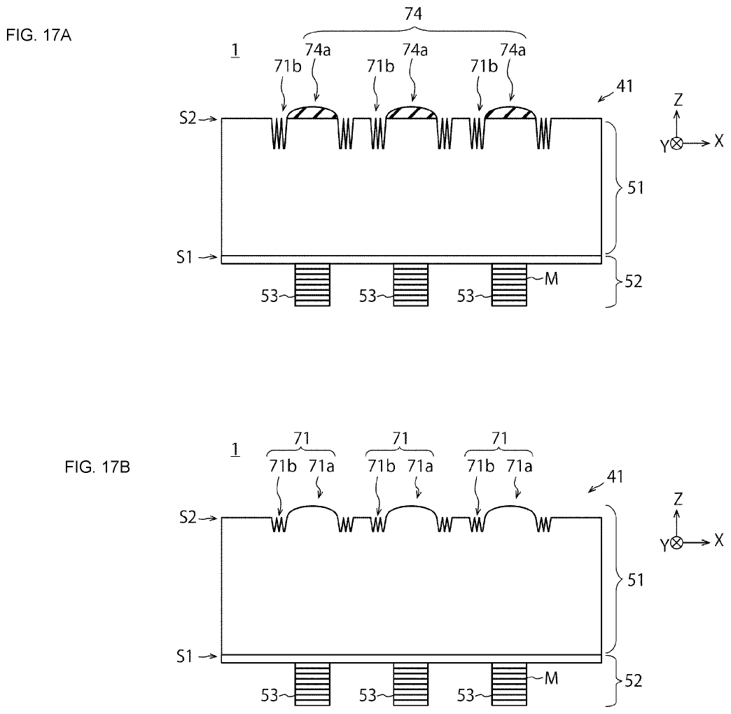

FIGS. 16 and 17 are cross-sectional views illustrating a manufacturing method for a light emitting device 1 according to a modification of the first embodiment.

First, after the laminated film 52 and the light emitting element 53 are formed on the front surface S1 of the substrate 51, the second structure body 71b of each structure body 71 is formed on the back surface S2 of the substrate 51 (A of FIG. 16). The second structure body 71b can be formed by, for example, the steps illustrated in A to C of FIG. 15. At this time, each mask portion 73 is formed so as not to include the first mask portion 73a but to include the second mask portion 73b.

The second structure body 71b illustrated in A of FIG. 16 is a scatterer. However, a height of each protrusion of the second structure body 71b illustrated in A of FIG. 16 is higher than a height of each protrusion illustrated in FIG. 4, in consideration that the back surface S2 of the substrate 51 and a front surface of each protrusion are to be scraped in a step described later.

Next, a mask film 74 is formed on the back surface S2 of the substrate 51 (B of FIG. 16). The mask film 74 is, for example, a resist film.

Next, the mask film 74 is processed into a shape including a mask portion 74a having the same shape as the first structure body 71a of each structure body 71 (A of FIG. 17). The processing of the mask film 74 may be performed by, for example, grayscale lithography and dry etching, or may be performed by imprinting. Each mask portion 74a illustrated in A of FIG. 17 has a shape of a convex lens, and is formed at a position surrounded by the corresponding second structure body 71b.

Next, the back surface S2 of the substrate 51 is processed by dry etching using the mask film 74 as an etching mask (B of FIG. 17). As a result, a shape of the mask film 74 is transferred to the substrate 51, and the first structure body 71a of each structure body 71 is formed on the back surface S2 of the substrate 51. That is, each structure body 71 is processed into a shape including the first structure body 71a and the second structure body 71b.

In this way, the light emitting device 1 illustrated in FIG. 4 is manufactured. According to the present method, after the second structure body 71b of each structure body 71 is formed on the back surface S2 of the substrate 51, the first structure body 71a of each structure body 71 can be formed on the back surface S2 of the substrate 51. That is, according to the present method, the first structure body 71a and the second structure body 71b of each structure body 71 can be sequentially formed on the back surface S2 of the substrate 51. In the present method, the second structure body 71b of each structure body 71 may be formed on the back surface S2 of the substrate 51, after the first structure body 71a of each structure body 71 is formed on the back surface S2 of the substrate 51. Note that, at a time of manufacturing of the light emitting device 1 of any of the modifications described above, the mask portion 73 (the second mask portion 73b) for forming the second structure body 71b of the modification and the mask portion 74a for forming the first structure body 71a of the modification are formed by steps of A of FIG. 16 and A of FIG. 17.

According to the methods illustrated in A to C of FIG. 15, for example, the structure body 71 can be formed with a small number of steps. Whereas, according to the method illustrated in A of FIG. 16 to B of FIG. 17, for example, the structure body 71 can be precisely formed.

As described above, the light emitting device 1 of the present embodiment includes the plurality of structure bodies 71 that shapes light from the plurality of light emitting elements 53, and at least any of these structure bodies 71 includes the first structure body 71a through which the first portion La of the light is transmitted and the second structure body 71b having a function different from a function of the first structure body 71a and through which the second portion Lb of the light is transmitted. Therefore, according to the present embodiment, light from the light emitting element 53 can be suitably shaped such that light incident on the structure body 71 from the light emitting element 53 can be shaped in different modes in the first structure body 71a and the second structure body 71b.

Note that the light emitting device 1 of the present embodiment is used as a light source of a distance measuring device, but may be used in other modes. For example, the light emitting devices 1 of the present embodiment may be used as a light source of an optical device such as a printer, or may be used as an illumination device.

Although the embodiment of the present disclosure has been described above, the embodiment of the present disclosure may be implemented with various modifications without departing from the gist of the present disclosure. For example, two or more embodiments may be implemented in combination.

Note that the present disclosure can also have the following configurations.
(1)

A light emitting device including:
a substrate;
a plurality of light emitting elements provided on a first surface of the substrate; and
a plurality of structure bodies through which light emitted from the plurality of light emitting elements is transmitted, the plurality of structure bodies being provided on a second surface of the substrate, in which
each of the structure bodies includes a first structure body through which a first portion of the light is transmitted and a second structure body through which a second portion of the light is transmitted, the second structure body having a shape different from a shape of the first structure body.
(2)

The light emitting device according to (1), in which the first and second structure bodies have a shape in which the second structure body annularly surrounds the first structure body.
(3)

The light emitting device according to (1), in which a boundary surface between the first and second structure bodies is a plane.
(4)

The light emitting device according to (1), in which the first structure body is a lens, and the second structure body is a structure body other than a lens.
(5)

The light emitting device according to (4), in which the first structure body is a lens, and the second structure body is a scatterer.
(6)

The light emitting device according to (1), in which the first and second structure bodies are lenses having mutually different shapes.
(7)

The light emitting device according to (6), in which the first and second structure bodies are lenses having mutually different curvatures.
(8)

The light emitting device according to (1), in which at least any of the first and second structure bodies is a convex lens, a concave lens, or a flat lens.
(9)

The light emitting device according to (1), in which the first and second structure bodies are provided on the second surface of the substrate, as a part of the substrate.
(10)

The light emitting device according to (1), in which the plurality of light emitting elements and the plurality of structure bodies correspond to each other on a one-to-one basis, and light emitted from each light emitting element is transmitted through one corresponding structure body.
(11)

The light emitting device according to (1), in which the substrate is a semiconductor substrate containing gallium (Ga) and arsenic (As).
(12)

The light emitting device according to (1), in which light emitted from the plurality of light emitting elements is transmitted inside the substrate from the first surface to the second surface, and is incident on the plurality of structure bodies.
(13)

The light emitting device according to (1), in which the first surface of the substrate is a front surface of the substrate, and the second surface of the substrate is a back surface of the substrate.
(14)

The light emitting device according to (1), in which the first structure body condenses or diffuses light from each of the light emitting elements, and the second structure body scatters light from each of the light emitting elements.
(15)

The light emitting device according to (14), in which the first structure body collimates light from each of the light emitting elements.
(16)

A manufacturing method for a light emitting device, the manufacturing method including:
forming a plurality of light emitting elements on a first surface of a substrate; and
forming, on a second surface of the substrate, a plurality of structure bodies through which light emitted from the plurality of light emitting elements is transmitted, in which
each of the structure bodies is formed to include a first structure body through which a first portion of the light is transmitted and a second structure body through which a second portion of the light is transmitted, the second structure body having a shape different from a shape of the first structure body.
(17)

The manufacturing method for the light emitting device according to (16), in which the first and second structure bodies are simultaneously formed on the second surface of the substrate.
(18)

The manufacturing method for the light emitting device according to (16), in which the first and second structure bodies are formed by forming one of the first and second structure bodies and then forming another one of the first and second structure bodies.
(19)

A distance measuring device including:
a light emitting device including a plurality of light emitting elements configured to generate light, the light emitting device being configured to irradiate a subject with the light from the light emitting elements;
an imaging device configured to receive the light reflected by the subject and generate an image signal from the light; and
a distance measuring unit configured to measure a distance to the subject on the basis of the image signal generated by the imaging device, in which
the light emitting device includes:
a substrate;
the plurality of light emitting elements provided on a first surface of the substrate; and
a plurality of structure bodies through which light emitted from the plurality of light emitting elements is transmitted, the plurality of structure bodies being provided on a second surface of the substrate, and
each of the structure bodies includes a first structure body through which a first portion of the light is transmitted and a second structure body through which a second portion of the light is transmitted, the structure body having a shape different from a shape of the first structure body.
(20)

The distance measuring device according to (19), in which the distance measuring unit extracts, from the image signal, first data corresponding to the first portion of the light transmitted through the first structure body and second data corresponding to the second portion of the light transmitted through the second structure body.

### REFERENCE SIGNS LIST

1 Light emitting device
2 Imaging device
3 Control device
11 Light emitting unit
12 Drive circuit
13 Power supply circuit
14 Light-emitting side optical system
21 Image sensor
22 Image processing unit
23 Imaging-side optical system
31 Distance measuring unit
41 LD chip
42 LDD substrate
43 Mounting substrate
44 Heat dissipation substrate
45 Correction lens holding unit
46 Correction lens
47 Wiring
48 Bump
51 Substrate
52 Laminated film
53 Light emitting element
54 Anode electrode
55 Cathode electrode
61 Substrate
62 Connection pad
71 Structure body
71a First structure body
71b Second structure body
72 Mask film
73 Mask portion
73a First mask portion
73b Second mask portion
74 Mask film
74a Mask portion

1. Light emitting device (substrate 51, light emitting element 53, structure body 71, first structure body 71a, and second structure body 71b)
A light emitting device comprising:
a substrate;
a plurality of light emitting elements provided on a first surface of the substrate; and
a plurality of structure bodies through which light emitted from the plurality of light emitting elements is transmitted, the plurality of structure bodies being provided on a second surface of the substrate, wherein
at least any of the structure bodies includes a first structure body through which a first portion of the light is transmitted and a second structure body through which a second portion of the light is transmitted, the second structure body having a function different from a function of the first structure body.

2. Light emitting device (FIGS. 4 to 7)
The light emitting device according to claim 1, wherein the first and second structure bodies have a shape in which the second structure body annularly surrounds the first structure body.

3. Light emitting device (FIGS. 8 to 10)
The light emitting device according to claim 1, wherein a boundary surface between the first and second structure bodies includes a plane.

4. Light emitting device (FIG. 4, FIG. 7A, FIG. 7B, and FIG. 10B)
The light emitting device according to claim 1, wherein the first structure body includes a lens, and the second structure body includes a structure body other than a lens.

5. Light emitting device (FIG. 4, FIG. 7A, FIG. 7B, and FIG. 10B)
The light emitting device according to claim 4, wherein the first structure body includes a lens, and the second structure body includes a scatterer.

6. Light emitting device (FIG. 9A, FIG. 9B, and FIG. 10A)
The light emitting device according to claim 1, wherein the first and second structure bodies include lenses having mutually different functions.

7. Light emitting device (FIG. 9A, FIG. 9B, and FIG. 10A)
The light emitting device according to claim 6, wherein the first and second structure bodies include lenses having mutually different curvatures.

8. Light emitting device (FIG. 4 and the like)
The light emitting device according to claim 1, wherein at least any of the first and second structure bodies includes a convex lens, a concave lens, or a flat lens.

9. Light emitting device (FIG. 4 and the like)
The light emitting device according to claim 1, wherein the first and second structure bodies are provided on the second surface of the substrate, as a part of the substrate.

10. Light emitting device (FIG. 4 and the like)
The light emitting device according to claim 1, wherein the plurality of light emitting elements and the plurality of structure bodies correspond to each other on a one-to-one basis, and light emitted from each light emitting element is transmitted through one corresponding structure body.

11. Light emitting device (substrate 51: GaAs substrate)
The light emitting device according to claim 1, wherein the substrate includes a semiconductor substrate containing gallium (Ga) and arsenic (As).

12. Light emitting device (substrate 51: back-side emission type VCSEL)
The light emitting device according to claim 1, wherein light emitted from the plurality of light emitting elements is transmitted inside the substrate from the first surface to the second surface, and is incident on the plurality of structure bodies.

13. Light emitting device (substrate 51: back-side emission type VCSEL)
The light emitting device according to claim 1, wherein the first surface of the substrate includes a front surface of the substrate, and the second surface of the substrate includes a back surface of the substrate.

14. Light emitting device (FIG. 6 and the like)
The light emitting device according to claim 1, wherein the first structure body condenses or diffuses light from each of the light emitting elements, and the second structure body scatters light from each of the light emitting elements.

15. Light emitting device (FIG. 6 and the like)
The light emitting device according to claim 14, wherein the first structure body collimates light from each of the light emitting elements.

16. Manufacturing method (substrate 51, light emitting element 53, structure body 71, first structure body 71a, and second structure body 71b)
A manufacturing method for a light emitting device, the manufacturing method comprising:
forming a plurality of light emitting elements on a first surface of a substrate; and
forming, on a second surface of the substrate, a plurality of structure bodies through which light emitted from the plurality of light emitting elements is transmitted, wherein
at least any of the structure bodies is formed to include a first structure body through which a first portion of the light is transmitted and a second structure body through which a second portion of the light is transmitted, the second structure body having a function different from a function of the first structure body.

17. Manufacturing method (FIG. 15)
The manufacturing method for the light emitting device according to claim 16, wherein the first and second structure bodies are simultaneously formed on the second surface of the substrate.

18. Manufacturing method (FIGS. 16 to 17)
The manufacturing method for the light emitting device according to claim 16, wherein the first and second structure bodies are formed by forming one of the first and second structure bodies and then forming another one of the first and second structure bodies.

19. Distance measuring device (light emitting device 1, imaging device 2, distance measuring unit 31, substrate 51, light emitting element 53, structure body 71, first structure body 71a, and second structure body 71b)
A distance measuring device comprising:
a light emitting device including a plurality of light emitting elements configured to generate light, the light emitting device being configured to irradiate a subject with the light from the light emitting elements;
an imaging device configured to receive the light reflected by the subject and generate an image signal from the light; and
a distance measuring unit configured to measure a distance to the subject on a basis of the image signal generated by the imaging device, wherein
the light emitting device includes:
a substrate;
the plurality of light emitting elements provided on a first surface of the substrate; and
a plurality of structure bodies through which light emitted from the plurality of light emitting elements is transmitted, the plurality of structure bodies being provided on a second surface of the substrate, and
at least any of the structure bodies includes a first structure body through which a first portion of the light is transmitted and a second structure body through which a second portion of the light is transmitted, the second structure body having a function different from a function of the first structure body.

20. Distance measuring device (FIG. 1)
The distance measuring device according to claim 19, wherein the distance measuring unit extracts, from the image signal, first data corresponding to the first portion of the light transmitted through the first structure body and second data corresponding to the second portion of the light transmitted through the second structure body.
